(19) United States
(12) Patent Application Publication
(10) Pub. No.: US 2008/0237672 A1
(43) Pub. Date: Oct. 2, 2008

(54) High density memory

(76) Inventors: Brian S. Doyle, Portland, OR (US); Dinesh Somasekhar, Portland, OR (US); Robert Chau, Beaverton, OR (US)

Correspondence Address: TROP PRUNER & HU, PC, 1616 S. VOSS ROAD, SUITE 750, HOUSTON, TX, 77057-2631, US

(21) Appl. No.: 11/731,233

(22) Filed: Mar. 30, 2007

(51) Int. Cl. H01L 21/8242; H01L 27/108

(52) U.S. Cl. 257/296; 438/239; 257/E27.084; 257/E21.645

(57) ABSTRACT

In one embodiment of the invention, a method of forming a semiconductor device includes forming a dynamic random access memory using spacer-defined lithography.

### BACKGROUND

A folded bit line dynamic random access memory (DRAM) architecture includes one memory cell for every other bit line crossing a particular word line. Therefore, when a word line is pulsed during a read or write operation, every other bit line in the memory will be a switching bit line. Consequently, there is always a “non-switching” bit line between each pair of switching bit lines during read and write operations. In contrast, an open bit line DRAM architecture includes one memory cell for each bit line crossing a particular word line. In the open bit line architecture, therefore, switching bit lines are much closer to one another during read and write operations than in the folded bit line approach, and there is no intervening non-switching bit line. The open bit line architecture is capable of achieving a significantly greater cell density than the folded bit line architecture.

When forming features in a DRAM circuit, however, a designer may need to account for various design rules. The design rules may specify a minimum lithography pitch between DRAM features. For example, if the minimum pitch (“pitch”) were 60 nm, then a portion of a feature such as a transistor contact edge must be at least 60 nm from the corresponding edge of another transistor contact.

The open bit line architecture may be problematic because, for example, the transistor contacts may be spaced too near to each other when the fins are located at the minimum pitch. In other words, the transistor contacts may be closer than the minimum pitch allows. The folded bit line DRAM architecture may avoid this issue by leaving two times the minimum pitch between transistor contacts that share a word line, while transistor contacts that do not share a word line may be formed at approximately the minimum lithography pitch. This solution, however, may lead to memory that lacks optimal density.

### BRIEF DESCRIPTION OF THE DRAWINGS

The accompanying drawings, incorporated in and constituting a part of this specification, illustrate one or more implementations consistent with the principles of the invention and, together with the description of the invention, explain such implementations. The drawings are not necessarily to scale, the emphasis instead being placed upon illustrating the principles of the invention.

FIG. 1 is a flowchart which describes the steps of forming a DRAM in one embodiment of the invention.

FIG. 2 is a DRAM in an embodiment of the invention.

FIG. 3 is a DRAM in an embodiment of the invention.

FIG. 4 is an example of a folded bit line DRAM.

### DETAILED DESCRIPTION

The following description refers to the accompanying drawings. Among the various drawings the same reference numbers may be used to identify the same or similar elements. While the following description provides a thorough understanding of the various aspects of the claimed invention by setting forth specific details such as particular structures, architectures, interfaces, and techniques, such details are provided for purposes of explanation and should not be viewed as limiting. Moreover, those of skill in the art will, in light of the present disclosure, appreciate that various aspects of the invention claimed may be practiced in other examples or implementations that depart from these specific details. At certain junctures in the following disclosure descriptions of well known devices, circuits, and methods have been omitted to avoid clouding the description of the present invention with unnecessary detail.

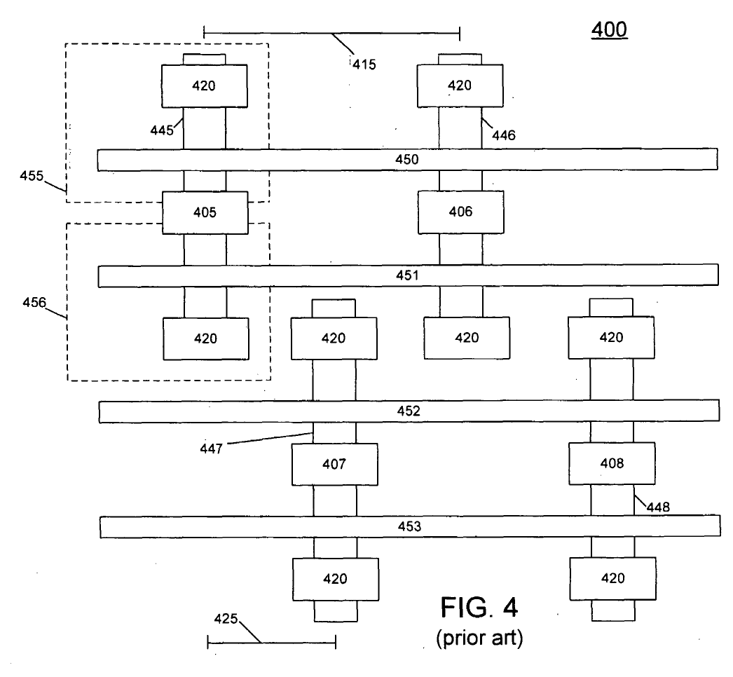

As stated above, an open bit line architecture may be problematic because, for example, transistor contacts may be spaced too near to each other if fins are formed at the minimum pitch from each other. The folded bit line architecture may offer a slight improvement. The folded bit line architecture, however, may lead to memory that lacks optimal density. For instance, FIG. 4 is an example of a traditional folded bit line DRAM 400. Semiconductor fins 445, 446 are associated with word lines 450, 451 and capacitors 420. Representative memory cells 455, 456 are depicted with hash marks. Semiconductor fins 447, 448 are associated with word lines 452, 453 and capacitors 420. Using traditional lithography, certain features (e.g., transistor contacts) that share a word line may be formed at approximately two times the minimum lithography pitch while other features (e.g., semiconductor fins) that do not share a word line may be formed at approximately the minimum lithography pitch. For example, semiconductor fins 445, 446 associated with the same word line 450 may be formed at twice the minimum lithography pitch 415. Furthermore, transistor contacts 405, 406 associated with the same word line 450 may be formed at a distance 415 that is twice the minimum lithography pitch. Semiconductor fins 445, 447 associated with different word lines 451, 452, however, may be formed at a distance 425 that is substantially equal to the minimum lithography pitch. Thus, while the folded bit line architecture may be offer a slight improvement over open bit line architecture in terms of allowable density, this solution may also lead to memory that lacks optimal density due to, for example, transistor contacts 405, 406 formed at a distance 415 that is twice the minimum lithography pitch.

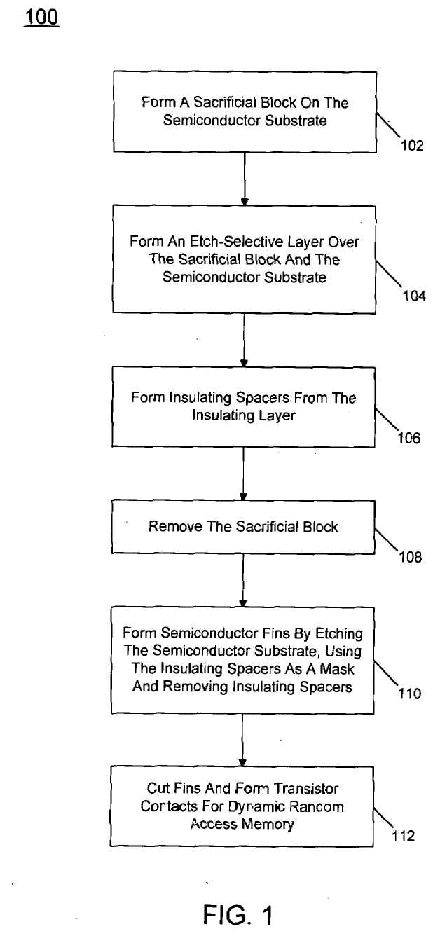

In contrast, an embodiment of the present invention employs spacer-defined lithography that, when used in conjunction with folded bit line DRAM architecture, may allow certain features to be formed more densely than was previously the case. FIG. 1 is a flowchart 100 which describes the steps of forming a folded bit line DRAM using spacer-defined lithography in one embodiment of the invention. Sacrificial blocks, each having a top surface and laterally opposite sidewalls, may be formed on a semiconductor substrate, as described in block 102. In one embodiment of the present invention, each sacrificial block is formed by first forming a layer of the sacrificial material and patterning the sacrificial material to form a block using lithography. The sacrificial blocks may be comprised of oxide, but are not limited to oxide. The width of each sacrificial block determines the spacing of fins, which may be used to eventually form, for example, transistor contacts and other features as discussed below. In one embodiment of the present invention, the laterally opposite sidewalls of each sacrificial block are 240 nm apart, which is approximately 1.5 times the minimum lithography pitch, taken to be 160 nm in this particular example. Other embodiments of the present invention may incorporate sidewalls of the sacrificial block that are closer to the minimum pitch such as, for example only, 1.25 times the minimum pitch. Still other embodiments of the present invention may incorporate sidewalls of the sacrificial block that are further from the minimum pitch such as, for example only, 1.75 or 2 times the minimum pitch. The distance between the laterally opposite sidewalls may be based on design rules and minimum lithography pitch.

After forming the sacrificial block, an etch-selective layer is formed over and around the sacrificial blocks and the semiconductor substrate, as described in block 104. The etch-selective layer may be comprised of a nitride or another etch-selective material. The etch-selective layer is deposited such that the thickness of the layer is approximately equal to the desired semiconductor fin width. In one embodiment of the present invention, the thickness of the etch-selective layer is between 5 and 30 nm. In another embodiment of the present invention, the thickness of the etch-selective layer is 15 nm.

Etch-selective spacers are then formed on each side of each sacrificial block by performing, for example, a reactive ion etch (“RIE”) on the etch-selective layer, as described in block 106. After the RIE etch, etch-selective spacers will remain on either side of the sacrificial block. The width of the etch-selective spacers will be equal to the thickness of the original etch-selective layer. In one embodiment of the present invention, the etch-selective spacers are 15 nm wide.

After the etch-selective spacers are formed, each sacrificial block may be removed by conventional methods, as shown in block 108. For example, a selective wet etch process may be used to remove each sacrificial block, while the etch-selective spacers remain intact.

Next, semiconductor fins are formed by etching the semiconductor substrate using the etch-selective spacers as a mask, as shown in block 110. The semiconductor fin is etched away in areas not covered by the etch-selective spacers, exposing the substrate. Each etch-selective spacer may then be removed by conventional methods, leaving multiple semiconductor fins. Each semiconductor fin formed has a top surface and a pair of laterally opposite sidewalls. Using the etch-selective spacers as a mask allows, if one so desires, the fins to be separated by a distance that is less than the distance that could be achieved using current lithographic technology (i.e., lithography pitch). Current lithography allows printing of features having minimum sizes near 40 nm and minimum spacing between features of near 120 nm. However, future lithography methodologies may allow distances of, for example, 32, 22, and 16 nm. Using an embodiment of a method according to the present invention, the fins can be formed less than 40 nm apart.

As shown in block 112, the semiconductor fins may then be cut into smaller individual fins using traditional lithography processes (e.g., CUT or TRIM processes). DRAM cells may then be formed. For example, transistor contacts may be formed on the semiconductor fins. The transistor contacts may be coupled to bit lines and transistors.

Thus, when spacer-defined lithography is used in conjunction with folded bit line DRAM architecture, certain features (e.g., transistor contacts) associated with different word lines may be formed at, less than, or greater than the minimum lithography pitch. Certain features (e.g., transistor contacts) that share a word line may be formed more densely than was previously the case. For example, with blocks formed at 1.5 times the minimum lithography pitch, semiconductor fins associated with the same word line may be formed at 1.5 times the minimum lithography pitch. Furthermore, with blocks formed at 1.5 times the minimum lithography pitch, transistor contacts associated with the same word line may be formed at 1.5 times the minimum lithography pitch. Examples are provided below.

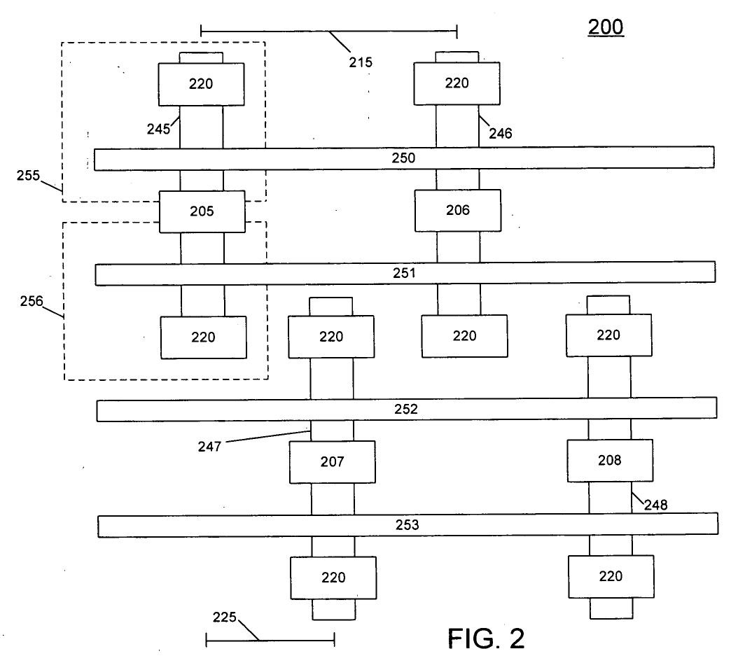

FIG. 2 is a folded bit line DRAM 200 in one embodiment of the invention. Semiconductor fins 245, 246 are associated with word lines 250, 251 and capacitors 220. Representative memory cells 255, 256 are depicted with hash marks. Semiconductor fins 247, 248 are associated with word lines 252, 253 and capacitors 220. Using the spacer-defined lithography methodology set out above, certain features that share a word line may be formed more densely than was previously the case. For example, with blocks formed at 1.5 times the minimum lithography pitch, semiconductor fins 245, 246 associated with the same word line 250 may be formed at 1.5 times the minimum lithography pitch. Furthermore, transistor contacts 205, 206 associated with the same word line 250 may be formed at a distance 215 that is 1.5 times the minimum lithography pitch. In addition, semiconductor fins 245, 247 associated with different word lines 251, 252 may be formed at a distance 225 that, for example only, is less than the minimum lithography pitch. In other embodiments of the invention, the distance between the semiconductor fins, as well as the distance between other features (e.g., transistor contact), may be altered (e.g., made equal to or larger than the minimum lithography pitch) based on, for example, design rules and minimum lithography pitch.

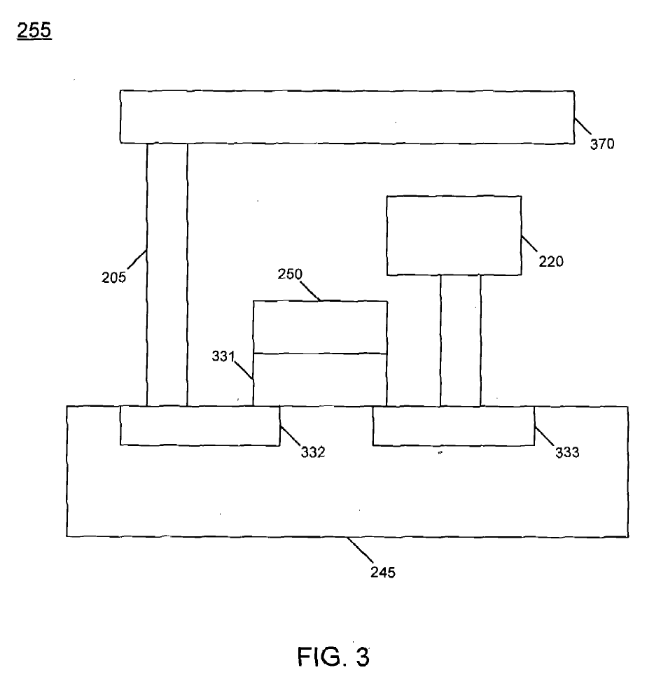

FIG. 3 is a folded bit line DRAM cell 255 (see FIG. 2) in an embodiment of the invention. Semiconductor fin 245 is associated with word line 250 and capacitor 220. Transistor contact 205 is coupled to bit line 370 and transistor source 332. Word line 250 is coupled to transistor gate 331. Transistor drain 333 is coupled to capacitor 220. The formation depicted includes forming a capacitor under a bit line. However, other formations are possible. For example, a trench capacitor may also be utilized.

While the present invention has been described with respect to a limited number of embodiments, those skilled in the art will appreciate numerous modifications and variations therefrom. It is intended that the appended claims cover all such modifications and variations that fall within the true spirit and scope of this present invention.

What is claimed is:

1. A method of forming a semiconductor device, comprising:
forming a plurality of sacrificial blocks on a substrate using a lithography method that includes a minimum lithography pitch, each of the sacrificial blocks having laterally opposite sidewalls and each of the sacrificial blocks separated from all other sacrificial blocks by a distance greater than the minimum lithography pitch;
depositing an etch-selective layer over each sacrificial block and the substrate;
forming an etch-selective spacer on each of the laterally opposite sidewalls of each sacrificial block by performing an etch on the etch-selective layer;
removing each of the sacrificial blocks;
forming a plurality of silicon fins by etching the substrate using the etch-selective spacers as a mask, wherein each silicon fin has a top surface and a pair of laterally opposite sidewalls and the plurality of silicon fins includes a first fin and a second fin;
removing the etch-selective spacers to expose the top surface of the first fin and the second fin; and
forming a first transistor contact on the top surface of the first fin and a second transistor contact on the top surface of the second fin,
wherein the first transistor contact is separated from the second transistor contact by less than twice the minimum lithography pitch.

2. The method of claim 1, wherein the first transistor contact is separated from the second transistor contact by no more than 1.5 times the minimum lithography pitch.

3. The method of claim 1, wherein the semiconductor device comprises a folded bit line dynamic random access memory (DRAM).

4. The method of claim 3, wherein the first transistor contact is separated from the second transistor contact by less than 160 nm.

5. The method of claim 3, wherein the DRAM includes one capacitor and one access transistor for every DRAM cell.

6. The method of claim 4, wherein a bit line is coupled to at least one of the transistor contacts.

7. The method of claim 1, wherein each of the sacrificial blocks is comprised of an oxide.

8. The method of claim 1, wherein each of the etch-selective spacer is comprised of a nitride.

9. A semiconductor memory apparatus comprising:
a first bit line formed using a lithography method, the lithography method including a minimum lithography pitch;
a first transistor coupled to a first semiconductor fin;
a first transistor contact coupled to the first bit line and to the first semiconductor fin;
a second bit line;
a second transistor coupled to a second semiconductor fin;
a second transistor contact coupled to the second bit line and to the second semiconductor fin; and
a word line coupled to the first transistor and to the second transistor;
wherein the first transistor contact is separated from the second transistor contact by less than twice the minimum lithography pitch.

10. The apparatus of claim 9, wherein the first transistor contact is separated from the second transistor contact by no more than 1.5 times the minimum lithography pitch.

11. The apparatus of claim 10, wherein the first transistor contact is separated from the second transistor contact by no more than 160 nm.

12. The apparatus of claim 9, wherein the first semiconductor fin is separated from the second semiconductor fin by no more than 1.5 times the minimum lithography pitch.

13. The apparatus of claim 9, further comprising:
a third transistor coupled to a third semiconductor fin and a third transistor contact; and
a second word line coupled to the third transistor;
wherein the first semiconductor fin is separated from the third semiconductor fin by about the minimum lithography pitch.

14. The apparatus of claim 13, wherein the first semiconductor fin is separated from the third semiconductor fin by less than the minimum lithography pitch.

15. The apparatus of claim 9, wherein the semiconductor memory includes a folded bit line dynamic random access memory (DRAM).
